(19) United States
(12) Patent Application Publication
(10) Pub. No.: US 2015/0077938 A1
(43) Pub. Date: Mar. 19, 2015

(54) VARIABLE CONDUCTANCE THERMOSIPHON

(71) Applicant: DANTHERM COOLING A/S, SKIVE (DK)

(72) Inventor: Morten Espersen, Bologna (IT)

(73) Assignee: DANTHERM COOLING A/S, SKIVE (DK)

(21) Appl. No.: 14/400,226

(22) PCT Filed: May 8, 2013
(86) PCT No.: PCT/DK2013/050132

§ 371 Date: Nov. 10, 2014

(30) Foreign Application Priority Data
May 11, 2012 (DK) PA 2012 70242
Aug. 24, 2012 (DK) PA 2012 70505

(51) Int. Cl. F28D 15/02; H05K 7/20; F28D 15/06

(52) U.S. Cl. CPC F28D 15/025; F28D 15/02; F28D 15/0275; F28D 15/06; H05K 7/20309; H05K 7/20318; H05K 7/20418; F28D 2015/0216
USPC 361/700; 165/104.21

(57) ABSTRACT

The present invention relates cooling system comprising at least one Thermo syphon, which Thermo syphon comprises at least one indoor evaporator, which is by first tubing connected to at least one outdoor condenser. It is the object of the present application to achieve effective automatic cooling of electronic systems placed inside a housing. This can be achieved by a system as disclosed in that the second tubing comprises a valve, which valve comprises a valve seat and a moveable valve piston, which valve piston is by decreasing temperature by the actuator moving towards the valve seat for closing the valve. Hereby a highly efficient cooling system can be achieved which can operate automatically without any energy supply from the outside, due to the use of the Thermo syphon principle. In situations where the outdoor temperature is decreasing to a low level which could occur in situations where the outdoor condensers in winter periods is cooled to a low temperature, there is a valve, which reduces or stops condensate and liquid refrigerant backwards to the evaporator.

### FIELD OF THE INVENTION

The present invention relates cooling system comprising at least one thermo siphon, which thermo siphon comprises at least one indoor evaporator which indoor evaporator is heat conductive connected to indoor cooling fins, in which indoor evaporator liquid refrigerant is evaporated, which indoor evaporator is by first tubing connected to at least one outdoor condenser which first tubing conduct evaporated refrigerant from the evaporator to the outdoor condenser, which outdoor condenser is heat conductive connected to outdoor cooling fins for cooling the condenser, which condenser is place en a defined vertical distance to use the gravity to generate a flow of liquid refrigerant from the condenser through a second tubing back to the evaporator.

### BACKGROUND OF THE INVENTION

US2011048676A discloses A cooling system applying a thermo siphon therein, being superior in energy saving and/or ecology, with an effective cooling, and also an electronic apparatus applying that therein, in particular, for cooling a CPU mounted on a printed circuit board within a housing thereof, comprises a heat-receiving jacket, being thermally connected with a surface of the CPU generating heats therein, and for evaporating liquid refrigerant stored in a pressure-reduced inner space with heat generation thereof, a condenser for receiving refrigerant vapour from the heat-receiving jacket within a pressure-reduced inner space thereof and for condensing the refrigerant vapour into a liquid by transferring the heats into an outside of the apparatus, a vapour tube, and a liquid return tube, with applying the thermo siphon for circulating the refrigerant due to phase change thereof, wherein the condenser forms fine grooves on an inner wall surface thereof along a direction of flow of the refrigerant, and is also formed flat in a cross-section thereof, for cooling the refrigerant vapour from the heat-receiving jacket on the inner wall surface thereof, efficiently.

### OBJECT OF THE INVENTION

It is the object of the present application to achieve effective automatic cooling of electronic systems placed inside a housing. A further object of the present application is to stop the cooling system in situations with low outdoor temperature and avoid cooling of the electronic system inside the housing when temperature is low and there is limited or no need for cooling.

### DESCRIPTION OF THE INVENTION

The object can be fulfilled by a system as disclosed in the opening paragraph an further modified in that the second tubing comprises a valve, which valve comprises a valve seat and a moveable valve piston, which valve piston is moved by a valve actuator, which valve piston is by decreasing temperature by the actuator moving towards the valve seat for closing the valve.

Hereby a highly efficient cooling system can be achieved which can operate automatically without any energy supply from the outside, due to the use of the thermo siphon principle. The energy supply necessary for operation is the heating that is used for evaporating the refrigerant in the evaporator. Because the thermo siphon is an open circuit with very limited flow restriction, a highly efficient cooling can be achieved. As long as the temperature inside a housing is higher than the outside temperature, the thermo siphon will operate very efficiently. In situations where the outdoor temperature is decreasing to a low level which could occur in situations where the outdoor condensers in winter periods is cooled to a low temperature, which have the unwanted effect that the inside of the housing is cooled to an undesirable low temperature level. In such situations there is a risk that very cold liquid refrigerant will be led through the tubing towards the evaporator which evaporator in this situation will start cooling inside the housing to a temperature level near the outside temperature. By the invention according to the present application this is avoided because there is a valve in the line that transmits condensate and liquid refrigerant backwards to the evaporator. If an automatic valve is formed that is heat-sensitive, then the valve will be close and the circulation stop as soon as the temperature in the liquid refrigerant is decreasing to a certain level. Of course with the valve closed, the thermo siphon is no longer in operation, but the outdoor temperature is so low that there is less cooling demand. Depending on the cooling demand the valve could fully close or partly close. In situations where the valve is designed to start closing, the thermo siphon is typically operating at temperature differentials higher than normal because the fan speeds is reduced in these operating situations. This have an undesirable effect on the thermodynamics processes driving the coolant circulation inside the thermo siphon, which in turn facilitates that the liquid is collected in the cold condenser disagreeing gravity. This effect is known as dry boiling the evaporator. As this thermodynamic state is metastable, the liquid will eventually return to the evaporator almost momentarily separated by certain time intervals producing a very undesirable shock cooling effect—as this collapsing process tends to happen very quickly. The valve inhibits or reduces this undesirable behaviour, as it blocks or limits the liquid return flow. If the valve is designed carefully it can prohibit dry boiling occurring because the thermal resistance of the thermo siphon is increased at low temperatures, which in turn prohibit the thermodynamic state necessary to effect dry boiling, from occurring.

The valve seat and the front of the valve piston can be conical. By the invention according to the present patent application it is possible to use different valve seats and different valve closure elements, but to achieve an efficient thermo siphon there must be an almost unrestricted flow refrigerant through the valve when the valve is in an open position. One possible way of achieving a high degree of opening is to use a conical valve seat and also a conical valve piston. In this way the refrigerant can flow around the conical valve piston and in this way it can be achieved that the flow restriction as such is very low for the liquid refrigerant flowing through the valve. In a closed position of the valve, there will be an efficient closure between the conical valve seat and the conical valve piston. Between the two conical elements a relatively long closure distance can be achieved. If further closure has to be achieved, there is no doubt that the conical piston or the conical seat could comprise one or more recesses in which O-rings could be placed, and in this way an even more efficient closure could be achieved.

In an alternative embodiment the valve can comprise a shaft, which shaft connects the valve piston through a valve seat. The valve actuator can be placed in thermal contact with the liquid refrigerant flowing in the second tubing, which valve actuator comprises a wax, which wax has a decreasing volume by decreasing temperature. One possible embodiment of the present invention is to use wax or maybe some other lubricant in an actuator because this actuator then maybe could comprise a movable piston that is moved by decreasing volume of the wax or lubricant contained in the volume. In a thermo siphon it should be possible to use a relatively long cylinder filled with wax or lubricant and in this way obtain a piston that can comprise the valve closure placed on the piston so that the valve will close automatically on decreasing temperature.

The valve actuator comprises at least one spring, which spring makes the valve piston acting towards the valve set for closing the valve. Hereby it can be achieved that a spring can press the valve piston against the valve seat and operate against the liquid pressure that occurs because a higher level of liquid is placed in the tubing above the valve. The spring has to be adjusted very precisely according to the force that is necessary for opening the valve. Different springs or different lengths of springs can be used in order to achieve different opening characteristics of the valve. In order to protect the valve, it could be possible to let the spring operate inside a housing which housing could also support the back-end of the spring and let the valve piston be placed at the front of the spring.

The valve actuator can be a bellow, which bellow comprises a gas, which is non-condensable in the operation temperature level for which the system is designed. In a preferred embodiment of the invention, a bellow is used because a bellow is a highly efficient component widely used in thermostats also for automatic opening and closing in relation to decreasing temperatures. The bellow will be filled with a non-condensable gas r which probably has a pressure near the boiling temperature/pressure of the operating refrigerant in the thermo siphon system, at which the valve has to operate. Thus it is only a question of selecting the pressure to define the operating temperature of the bellow valve that is to be used inside the bellow. Alternatively refrigerants or a mixture of several refrigerants could be used instead of a gas. By using a mixture is should be possible to adjust the boiling point rather precisely in a way so that boiling will occur over a temperature range. The internal pressure and bellow should make it possible also to use springs, maybe a spring that operates against the opening direction of the bellow, so that, as soon as the pressure in the bellow is reduced, the spring contributes to opening the valve and vice versa. The operating refrigerant is outside the bellow and the pressure of this is acting on the bellow. When the temperature/pressure of the saturated operating refrigerant is higher than the non-condensable gas inside the bellow the valve is open. When the saturation temperature/pressure inside the thermo siphon falls below the non-condensable pressure inside the bellow plus the force from the bellow spring times the area, the bellow begins to close The operation band of the bellow is then defined by the pressure differentials times the area on the one hand and the spring characteristics on the other hand.

It should also be possible to use a bimetal spring which bimetal spring automatically changes its length independently of the temperature. The valve piston could be fixed through one end of the bimetal spring, and the other end could be fixed in relation to the tubing.

A conical valve seat can be formed inside a first section of the tube, which first section comprises a first small diameter and a second section which second section has a second larger diameter, which conical valve seat connect the first section small section with the lager section. Hereby a highly efficient valve seat generation inside the tube can be achieved because the tube diameter is increased. By increasing the diameter of the tube just after the valve seat, it can be achieved that the flow can pass the actuator and valve piston in a rather undisturbed way because the flow can go just around the conical valve piston and the flow is automatically divided in a circular direction around the centrally placed actuating means.

In a preferred embodiment for the invention can the valve be formed as a valve unit, which valve unit comprises a valve seat formed in a clips, which clips comprises one or more legs, which legs comprises fastening means for a reference plate, which reference plate caries a first end of a bellow, which bellow at a second end comprises a valve piston. In this way the valve can operate as a spring by itself, but a spring that comprises a gas such as a refrigerant which gas at the operating temperatures, is supposed to be in the gaseous phase. Using the so-called clips just for supporting the reference plate and also at the same component comprises the valve seat it is possible to achieve a highly efficient valve based on a bellow where the clips defines both the level of the reference plate and also by itself comprises the valve seat. Therefore no further adjustment of the distance between the bellow and the valve seat are necessary. Because the clips is pressed into contact with the reference plate and fastened with a second clips, the distance is very precise and achieved for the whole life of the valve unit. Hereby a very efficient valve unite is achieved by which the actual operating pressure and operating temperature can partly be adjusted by the selection of the gas that is inside the bellow. Temperature and thereby actual force of the bellow can easily be adjusted by the selection of the gas or by the pressure of the gas that is filled into the bellow. There will be a relation between temperature and gas pressure inside the bellow and the pressure and temperature of the refrigerant that is circulated outside the bellow. Because of the thermal conductivity of the bellow, the temperature inside the valve will be very close to the temperature outside the bellow, so far, no rapid temperature changes will take place. Therefore, a more or less automatic relation can be achieved, depending on the temperature of the refrigerant flowing around the valve.

In the preferred embodiment can the bellow comprise an inner support, which inner support comprises a tube placed inside the bellow, which inner support comprise a collar, which collar is fastened to the first end of the bellow. Hereby a highly efficient stabilization of the bellow is achieved so that the bellow at the outside is stabilized by the legs of the clips, and inside, the bellow is stabilized by the inner cylinder. The inner cylinder also defines how deep the valve piston can be pressed down because at a certain level, the inner side of the valve piston will be in touch with the top of the cylinder, and thereby an end stop is achieved. By fastening the collar toward the end plate, a very stable bellow construction is achieved. A further possibility is obtained by the inner support because the tube is hollow; inside the tube one additional spring can be placed that is pressing the valve piston towards contact with the valve seat.

The clips combined with the bellow and the inner support forms the valve unit, which valve unit is placed inside a section of a tube. Hereby it can be achieved that a valve unit ready to be placed in a cooling system can be prefabricated. In this way, traditional soldering operation of placing the valve unit in a new thermo siphon system or any other system where a pressure has to be controlled, the valve unit can be used.

In a preferred embodiment for the invention the valve comprises a cylinder, in which cylinder a hollow piston is operating, which hollow cylinder is mechanical connected to the first bellow, which hollow piston comprises a plurality of bleed openings, which bleed openings by movement of the piston in relation to the cylinder performs gradual opening of the valve. Hereby it can be achieved that the valve will start to open gradually so that by increasing pressure at the valve, only a small number of bleed holes, which number could be as few as two holes, because it is a good idea to achieve a symmetrical flow in order to avoid unbalanced in-flow forces that are achieved by the circulation of refrigerant. By increasing pressure, more bleed openings will be free from the cylinder and therefore an increasing flow is achieved. The number of bleed openings can be high, or instead it could be any other symmetrical openings that are used. Every form of opening could be used, the only technical arguments for forming bleed openings in the cylinder is that they must be designed to perform a mostly symmetrical flow of refrigerant. By a valve in which the opening is gradually increasing by further movement by a pressure difference, a variable valve can be achieved which is not an on/off valve. Probably, a position will be stable with a degree of opening that depends on the pressure. A slight change in pressure will immediately result in a slight change of the flow opening in the valve. Therefore, it can be achieved that the valve will automatically reach a position that is mostly correct to the actual cooling demand. By this variable valve, any hunting in the system should be prevented.

In a further preferred embodiment for the invention can the system comprises at least one second bellow, which second bellow is by at least one tube connected to at least one bulb, which second bellow and the bulb contain a second refrigerant, which second refrigerant is partly liquid in normal operation of the system, which second bellow opens the valve by increasing temperature. In order to solve a problem which can occur in situations where the actual pressure in the system is low, probably because the condenser is placed in a very cold position, the valve could be closed, but if the temperature in the housing is increasing, this could be a rather bad situation, and maybe the system is so cold that the valve will never open. Therefore the second bellow is used and activated by increasing indoor temperature in order to force the valve to open. In situations where the bulb is measuring a high indoor temperature, there will be an automatic opening of the valve independently of the actual pressure over the valve. Therefore, a cooling demand can be achieved in situations where otherwise temperature would increase to a high level before the system will start operating. By adjusting the refrigerant that is contained in the second bellow and in the bulb so that this refrigerant is both liquid and gas at the same time, it is possible, by the amount that is filled in, to adjust the temperature, so only in extreme situations, will the second bellow will activate the valve. Further, in atypical operation where the necessary cooling capacity varies, caused by varying heat dissipation of the system that needs to be cooled, the second bellow can be used to obtain a high level of temperature control for the system being cooled in situations where the low temperature primary bellow is closed due to low ambient temperatures.

The first bulb can be placed inside a housing, in which bulb the pressure depends of the indoor temperature, which increasing indoor temperature result in increasing pressure in both bulb and the second bellow, which second bellow forces the valve to open. Especially if the cooling system is used as a passive air conditioning system in buildings, which could be housing for electronic equipment, or any other housing where the temperature inside the housing is higher than the outside temperature. In order to avoid the disadvantages of passive cooling systems in situations where there is low condensation pressure where the valve automatically closes, it is necessary to avoid an increasing indoor temperature by measuring the indoor temperature and force the valve to open. This is achieved if the bulb is placed inside the housing, for example in the circulating air that circulates around the evaporator, then the valve will automatically be opened by the increasing temperature of the bulb, thereby increasing the pressure which pressure will automatically increase the pressure in the second bellow which will lead to opening of the valve. By rapid temperature increase, the delay of the system can be avoided as the valve opens very fast so that cooling is affected as soon as the temperature starts to increase.

In a further preferred embodiment for the invention the system can comprise at least a first circuit, which first circuit is operating continuously, which first circuit comprises a design gas, which design gas comprises a first refrigerant or refrigerant mixture, which deign gas further comprises a inactive gas, which inactive gas is in gas form in all operative condition, which circuit comprises a separator, which separator is connected to a at least one inactive gas cartridge.

Hereby can be achieved, that the gas mixture of the refrigerant and the inactive gas loses cooling efficiency at low temperatures and increases its efficiency at higher temperatures. This can be achieved because the refrigerant operates in this way of different boiling curves in a phase diagram. At very low temperatures, the refrigerant boiling process will mostly be prohibited, and the thermo syphon operation nearly ceases. Hereby it is achieved that the thermo syphon is dependent on actual power dissipation at the evaporator. In this way the first circuit can be self-adjusting without any manipulation of any valves. The efficiency is increasing by increasing temperatures up to a maximum. Probably this system operating with the design gas is operating in parallel with other systems which systems are operating by a closing valve so that these systems are prevented from any shock cooling effect. By having one circuit automatically adjusting the cooling effect, further circuits operating more primitively can work in parallel. These systems can then be adjusted so they are starting to operate by increasing temperatures. The number of parallel circuits are not limited to three as indicated in the figures, but a higher number is possible. Working with a high number of parallel operating systems makes it possible to remove heat from buildings for quite other purposes than for cooling electronic circuits.

In a further preferred embodiment for the invention can the separator be formed as a tank, which tank comprises a refrigeration inlet and outlet, which tank further comprises a inactive gas in and outlet, which tank comprises a lower volume for liquid refrigerant and a volume for a mixture of evaporated refrigerant and inactive gas. In the tank gravity will automatically separate liquid refrigerant from gaseous refrigerant. And the added gas will of course be mixed with the refrigerant gas. A connection to a cartridge at the top of a tank will lead to a situation where this cartridge comprises a mixture of gas and gaseous refrigerant. In the system there will exist equilibrium between gas that is carried in the liquid refrigerant and gas that is placed in the upper part of the tank and in the gas cartridge, provided quasi static isothermal conditions exists

It is preferred that the tank comprises a diaphragm or a membrane permeable only to the non-condensable gas for separating refrigerant and inactive gas. Placing a diaphragm over the surface of the refrigerant can isolate refrigerant totally for getting into the volume for the inactive gas. It is possible to design a diaphragm so that refrigerant molecules will be stopped by the diaphragm but the inactive gas, which probably has much smaller molecules, will penetrate the diaphragm with very little resistance. By the correct design of the diaphragm there will be an almost 100 per cent separation between refrigerant and inactive gas over the diaphragm. Hereby it is possible to adjust the fill ratio of the system more precisely thereby obtaining better performance and at the same time limit the amount of necessary refrigerant to operate the system. The inactive gas is always present below the membrane, but the molar fraction decrease with power increment and temperature increment. Nevertheless, the boiling temperature of the mixture is permanently altered prohibiting the boiling process below the specified minimum temperature of the system. By correct selection of inactive gas and refrigerant where also the actual volume could be rather important, as well as the pressure of the system, it should be possible to make a system more or less automatically working where the cooling effect is automatically adjusted. Such a system with no moving components could be very important for long-living cooling systems that should be able to operate automatically without any kind of service for several years.

In a preferred embodiment can the temperature of the inactive gas cartridge be regulated. By changing temperature of the gas cartridge it is also possible to change the actual volume and pressure of the inactive gas that is carried into the refrigerant. It is possible to place the heating elements outside the gas cartridge so that by electric connection the cartridge could be heated. Further it is possible that the gas cartridge is placed outside the building or housing so that outdoor temperature always is present at the gas cartridge. By then using the heating elements it is possible to change the contents of inactive gas in nearly all situations, simply by switching an electric switch on and off which could be performed by a computer control system. In many situations, the outdoor placement of the gas cartridge will be all that is necessary to establish an automatic system. The outdoor temperature will automatically have influence on the pressure inside the gas cartridge and therefore have influence on the amount of gas that is added to the refrigerant. Therefore it is simply a question of selecting the correct inactive gas in combination with the correct refrigerant. Inactive gases could for example be helium or argon. Also carbon dioxide is possible if carbon dioxide is inactive in relation to the refrigerant. Also so-called gasses with ideal gas characteristics could in fact be used. In one possible embodiment of the invention it is possible to reduce the cooling effect of the thermo syphon system simply by increasing the contents of inactive gas in the refrigerant. If the heating demand is decreasing, maybe in situations of low outdoor temperature, it is possible by correct concentration of inactive gas simply to heat the gas cartridge and in that way increase the pressure in the gas cartridge and increase the amount of gas in the refrigerant. Hereby the efficiency of the thermo syphon system can be decreased so that the cooling system as such is adjusted automatically to the actual cooling demand. In a situation where the outside temperature is relatively high, it is possible not to heat the gas cartridge and in that way reduce the contents of inactive gas in the refrigerant and in that way increase the efficiency of the cooling system. Hereby it can be achieved that a simple temperature control of a gas cartridge gives the possibility of controlling the efficiency of the entire cooling system.

The present patent application further concerns use of a system as disclosed in one of the claims 1-16 for cooling electronic systems, where electronic systems are placed inside a housing, which electronic systems generate heat, whereby the inner of the housing need cooling, which cooling is performed with at least on thermo siphon, which evaporator of the thermo siphon is placed inside the housing for the electronic system, which condenser of the thermo siphon is placed outside the housing.

Hereby it can be achieved effective cooling especially for electronic devices such as transmitter receiving system for mobile communication placed in small housings in relation to the communication or transformer housings placed near consumers. In all of these housing there is a climatic shield that is protecting the electro- or electronic devices inside but the devices inside the housing are producing heat which has to be removed. A plurality of thermo siphons can therefore be used because they perform the cooling of the housings rather efficiently but with very low energy consumption. The number of thermo siphons can be relatively high because when the thermo siphons has been installed there will be almost no service or operation costs. Therefore the evaporator can be placed inside the housing and the condenser can be placed outside the housing. In some situations circulating air will be used inside the housing so that air blowing means will blow air around the evaporators inside the housing and air blowing means could also be used for circulating outdoor air through the condensers. By the invention according to the present patent application it is achieved that if a situation occurs in which the outside temperature is decreasing, for example in winter cooling of the condensers can take place, the temperature of condenser is lower than the temperature of the evaporator inside the housing. In such a situation a rather unrestricted flow will occur from the condenser down to the evaporator, and the evaporator will be cooled near to the outdoor temperature. To avoid such a situation when the outdoor temperature is low, the valve is placed in the liquid line between the condenser and evaporator. As soon as the temperature decreases to a certain level, this valve will close full or partly and the thermo siphon as such will stop or reduce its operation until the temperature is increasing in the condenser, thereby increasing the temperature and pressure in the entire thermo siphon.

The present invention further concerns a method for operating a cooling system as disclosed in one of the claims 1-13 in a sequence of steps:

a. perform evaporation of refrigerant in a evaporator for generation a refrigerant gas,
b. let the gas flow in a piping towards a condenser placed a gravity level higher than the evaporator,
c. perform condensation in the condenser for generation of liquid refrigerant,
d. let the liquid refrigerant flow in a tubing towards a normal closet valve,
e. open the valve depending of the pressure of liquid refrigerant above the valve,
f. force by gravity the liquid refrigerant to flow in a piping back towards the evaporator.

By this method a thermo siphon system can be achieved which automatically stops or reduces the flow of refrigerant in a situation where the temperature is so low that less cooling capacity in Watt/Kelvin is needed. In such a situation, there will probably be decreased or no cooling demand. Therefore the closing of the valve will give as result that no or reduced further refrigerant is delivered to the evaporator. Thereby it is avoided that the evaporator is further cooled by sending very cold refrigerant down to the evaporator. In an indoor environment, for example a housing for electronic circuits, it will be possible to reduce the air flow for short periods of time thereby letting the temperature in the housing increase. The increasing temperature will relatively quickly lead to a low degree of evaporation in the evaporator. Evaporated gas will continue flowing in the piping towards the condenser. If the temperature around the condenser is very low, condensation takes place immediately. However, only if there is a certain pressure of refrigerant placed above the valve, there will be circulation back to the evaporator. If the valve is correctly adjusted, a defined temperature and thereby the pressure must be achieved to start a very limited circulation, and therefore an automatic adjustment of the amount of circulating refrigerant can be achieved. Increasing temperature at the evaporator will lead to a higher degree of evaporation which then automatically increase the pressure in the condenser and an increasing pressure in the liquid refrigerant will be achieved above the valve, which valve will then open more to t increase the flow of liquid refrigerant through the valve. This will probably relate to situations in the winter period. In the summer period, with high indoor and outdoor temperatures, the valve will probably be open most of the time so that full circulation can take place.

### DESCRIPTION OF THE DRAWING

FIG. 1 shows a cooling system comprising a plurality of thermo siphons operating in parallel.

FIG. 2 shows a detailed disclosure of a thermo siphon according to the present invention.

FIG. 3 shows a valve and valve housing.

FIG. 4 shows an alternative embodiment for the valve.

FIG. 5 shows a possible embodiment of valve unit.

FIG. 6 shows the various valve components before they are assembled.

FIG. 7 shows the valve unit seen in FIG. 5, now placed inside a tubing.

FIG. 8 shows a sectional view of a further embodiment for the invention.

FIG. 9 shows a preferred embodiment of a thermo syphon cooling system.

FIG. 10 shows one possible embodiment of a separator.

### DETAILED DESCRIPTION OF THE INVENTION

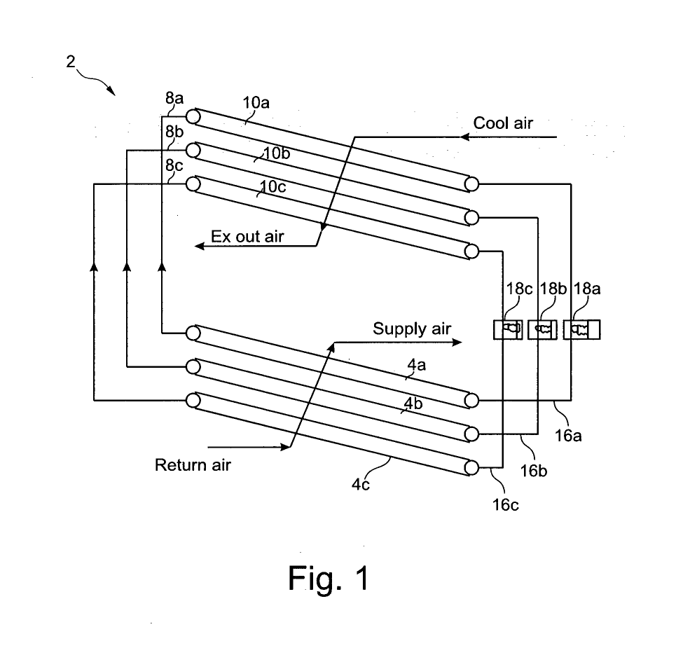

FIG. 1 shows a cooling system 2 which cooling system 2 comprises evaporators 4a, 4b, 4c. By tubing 8a, 8b, 8c the evaporators 4a, 4b, 4c are connected to condensers 10a, 10b, 10c. By tubing 16a, 16b, 16c the condensers are further connected through valves 18a, 18b, 18c back to the evaporators 4a, 4b, 4c.

In operation the evaporators 4a, 4b, 4c will all be placed inside a housing where for example air by an air blowing means will be blown along the evaporators. This flow of air will therefore be cooled. This leads to heating of the refrigerant that inside the evaporators 4a, 4b, 4c, and therefore boiling takes place in the evaporators. Heated and evaporated refrigerant is now flowing as a gas steam through the tubes 8a, 8b, 8c into the condensers 10a, 10b, 10c.

The condensers are placed outside the housing and cooled air is circulating along the condensers. Thereby heat is removed and condensation of the refrigerant will take place. Therefore liquid refrigerant will circulate through the valves 18a, 18b, 18c through the lines 16a, 16b, 16c.

By decreasing the outside temperature, cold liquid refrigerant will flow through the line 16a, 16b, 16c into the evaporator. Hereby is cooling to near the outdoor level performed inside of the housing. Therefore the valves 18a, 18b, 18c are placed in the return line 16a, 16b, 16c. By decreasing temperature, the valves 18a, 18b, 18c will automatically close and then stop circulation in the three thermo siphons. Hereby it is achieved that in situation with extremely low outdoor temperature, there will be reduced or no cooling effect in the circuits where the valve is in its operating temperature range. The valves can have different operating ranges in order for the valves to regulate at different temperatures facilitating a stepwise process at the outside temperature decreases.

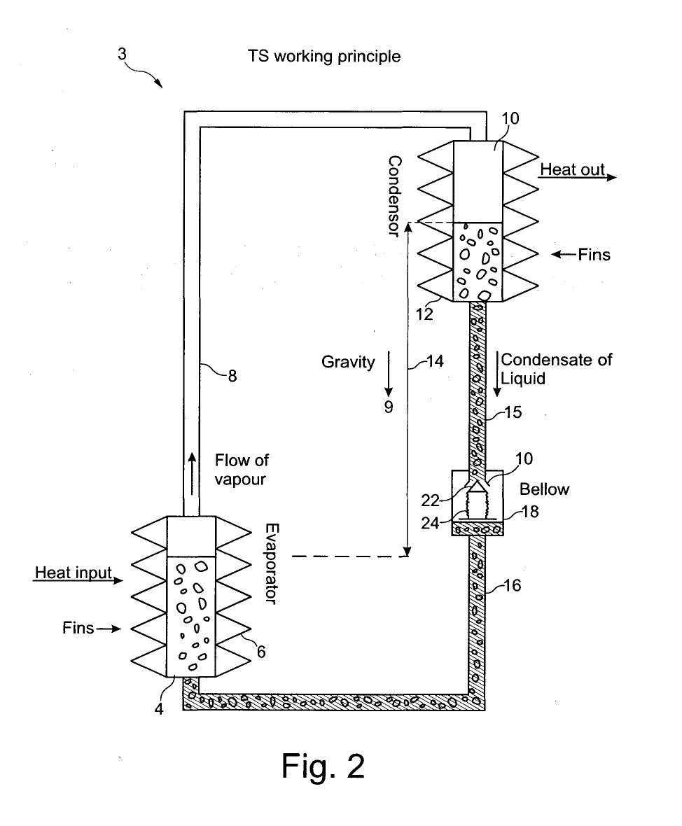

FIG. 2 shows a thermo siphon 3 according to the present invention. This thermo siphon comprises a first evaporator 4 which evaporator 4 has cooling fins connected to the outside of the evaporator 4 and from the evaporator 4 there is a tubing 8 connecting the evaporator 6 to an outdoor condenser 10. This outdoor condenser 10 is further connected to heating fins 12. The condenser 10 is further connected by the tubing 16 to a valve 18. This valve 18 comprises a valve seat 20 and a valve piston 22 and an actuator 24. The valve 20 is shown with an open position where liquid refrigerant flows in the line 16 back to the evaporator 4.

If the evaporator 4 is placed inside a housing for an electronic circuit, blowing means can perform cooling by the cooling fins 6 and the circulating air. Inside the evaporator a refrigerant will boil and thereby perform cooling. Evaporated refrigerant then circulates through piping 8 to the outside condenser where condensation is performed because the outdoor condenser is placed outside where the temperature is lower. Therefore condensation takes place inside the condenser, and liquid refrigerant is generated and will flow through the piping 16 down to the valve, and back into the evaporator.

In a situation where the temperature is decreasing, relatively cold refrigerant will flow in the tubing 16 towards the evaporator 4 and cooling the inside of the housing, cooling will be performed to a temperature neat the outside temperature. Therefore the valve 18 is placed in the return flow 16 of the refrigerant. By decreasing temperature in the flowing refrigerant, the valve 18 closes and the flow is interrupted or reduced. The decreasing temperature inside the housing can lead to reduced or no evaporation. In that situation will the pressure from the refrigerant acting at the valve piston 22 be reduced and the bellow and the gas inside the bellow is acting mostly like a spring against the refrigerant pressure and by reduced pressure at the valve piston 22 the valve 18 is closed.

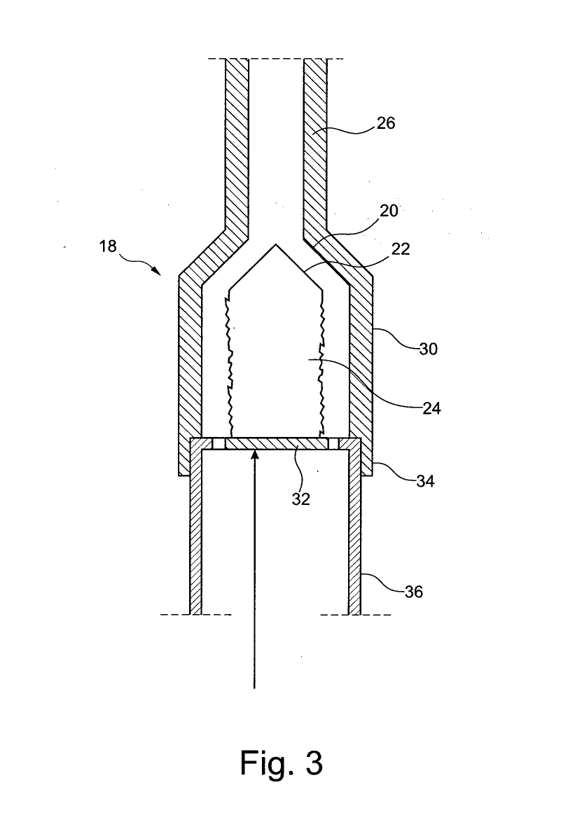

FIG. 3 shows a detailed view of the valve and the valve housing. FIG. 3 shows an inlet tube 26 which come from the condenser (not shown). The tube 26 ends in the conical valve seat 20. The conical valve seat 20 changes the diameter of the tubing into the tube 30 which forms housing for the valve 18. This valve 18 comprises the valve piston 22 and a bellow 24. This bellow 24 is supported by a support disc 32 which is placed below the bellow 24. Below the bellow 24 a tube 36 is further shown which is welded or soldered by the welding or soldering 34.

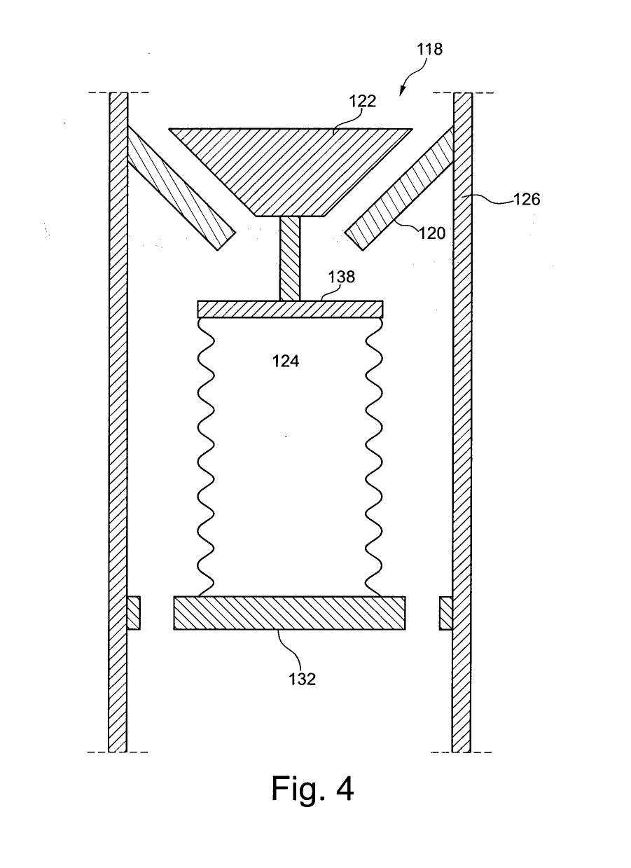

FIG. 4 shows a valve seat 120 which cooperates with a valve piston 122 placed inside a tube 126 which tube is the same as the one shown as 26 in FIG. 3. A valve actuator 124 is formed as a bellow which bellow 124 comprises a wax or lubricant or grease. The bellow 124 is supported by a support 132, and the bellow ends in the mechanical structure 138 to which a shaft 140 is connected. At its other end, this shaft 140 is connected to the valve piston 122.

In normal operation, the valve indicated in FIG. 4 will be in open position. Relatively warm condensed refrigerant is flowing around the bellow and in this way it keeps the temperature of the wax or lubricant or grease inside the bellow at a relatively high temperature. If the outside temperature is reduced, for example in the winter period, the volume of the bellow 124 is reduced, and the valve piston 122 is moving downwards towards contact with the valve seat 120, and in this way, the flow of refrigerant is closed.

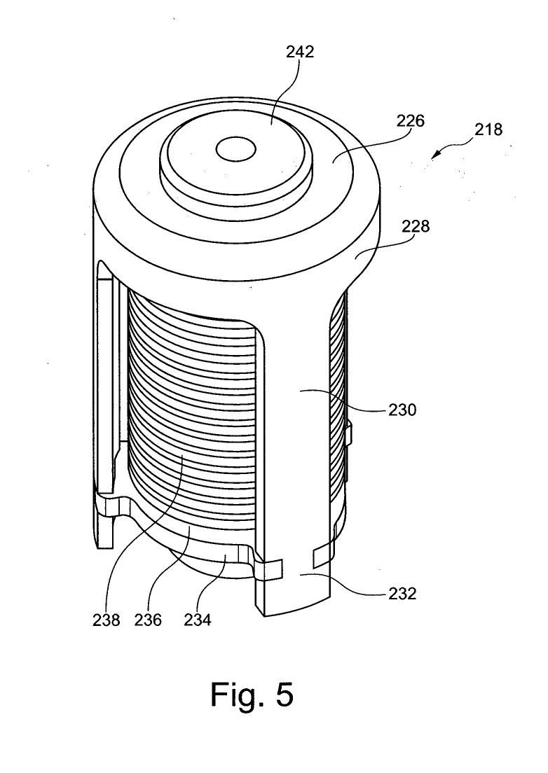

FIG. 5 shows a valve unit 218 which valve unit comprises a bellow 238 and a clips 228 which clips comprises three legs, 230. These legs 230 comprise fastening means, 232 for fastening a support 234. The clip 228 comprises a valve seat 226 which cooperates with valve piston 242. The reference plate 234 is thereby fastened towards the legs 230 by the fastening means 232. Thereby the reference plate 234 for the bellow 238 is achieved. The bellow 238 will act as a spring so a normally closed valve is achieved. The legs 230 are flexibly formed so the reduced distance between the legs is easily achieved by slide bending so that the legs can snap into a fixed locked position for the support plate 234.

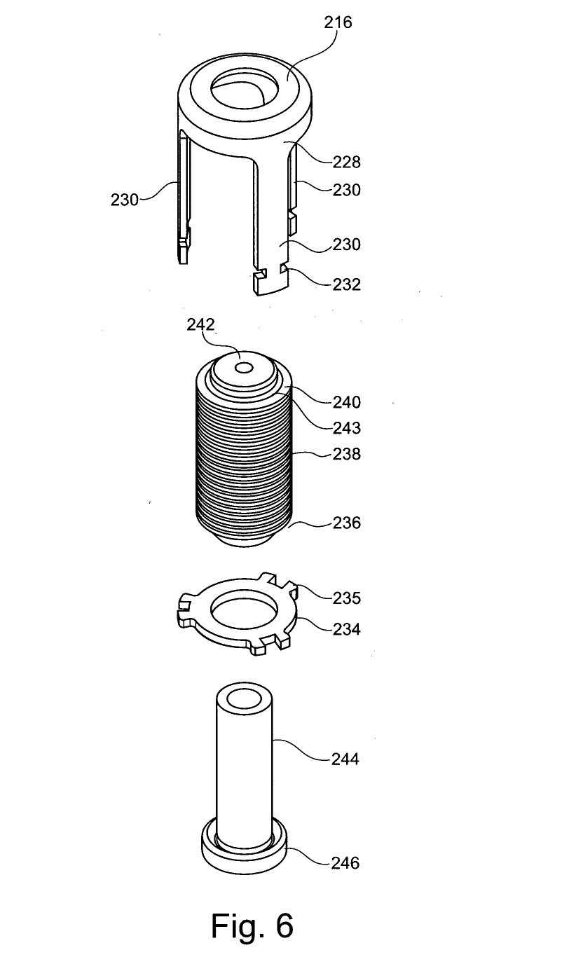

FIG. 6 shows an exploded view of a valve unit as indicated in FIG. 5 but now separated into various components. At first the clips 228 is shown which at its top comprises the valve seat 216. This valve seat is downwards oriented and, not directly indicated, formed with a conical surface. The clips 228 further comprises the flexible legs 230 which legs comprise cut-outs indicated as 232 for connection to the reference plate 236.

The bellow 238 has a first end 236 pointing towards the reference plate 234. The bellow 238 has its second upper end 240 which is connected to the valve piston 242. This valve piston comprises a conical surface 243 for interacting with the conical surface at valve seat 216.

The reference plate 234 comprises protrusions 235 for interacting with the cut-outs in the clips forming the fixation of the legs towards the reference plate.

Further an inner support 244 is indicated, which inner support comprises a collar 246 which collar 246 is intended for fastening towards the first end of the bellow 236. The inner support 244 can contain a spring inside which, when assembled, will exert a spring force towards the top of the bellow 238 and therefore further press the valve piston in a closing direction. Hereby one further possibility of adjusting the valve characteristics is achieved.

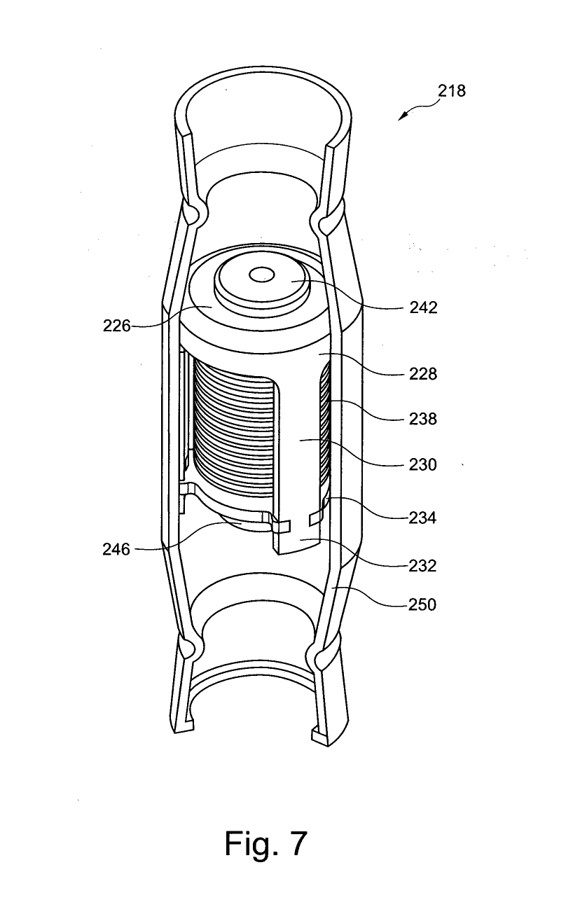

FIG. 7 shows the valve unit 218 placed in a tube 250. Inside the tube the clips 228 is indicated. The legs of the clips 230 and the reference plate 234 where the clips is fastened to the reference plate 234 by the fastening means 232. At the top, the valve seat 226 and partly the valve piston 242 are indicated. Just below the bellow the inner support and its collar 246 are indicated.

In operation, the valve unit 218 as placed in the tube 250 will be fastened inside the tube 250 by exerting an external pressure upon the tube 250 and in this way it will fix the tube. The tube has a further function in relation to the clips because the flexible legs of the clips will be totally locked when mounted in the tube thereby locking the reference plate 234 in correct position. There is, so to say, no possibility for the legs 230 to be bent even if they are flexible because they are surrounded by the tube 250. Hereby a valve unit in the tube 250 is achieved which can easily be used in cooling system, for example, because the tube 250 can be soldered into a fluid-tight connection with traditional piping of cooling systems. Hereby a valve can be achieved that is very easy to mount in a cooling system, and which valve is fully automatic and there is no need for any energy supply from the outside. This valve expected to have an extremely long service life because the valve as such with the bellow is well protected inside the tube and also protected by the circulating refrigerant that is circulating around the bellow.

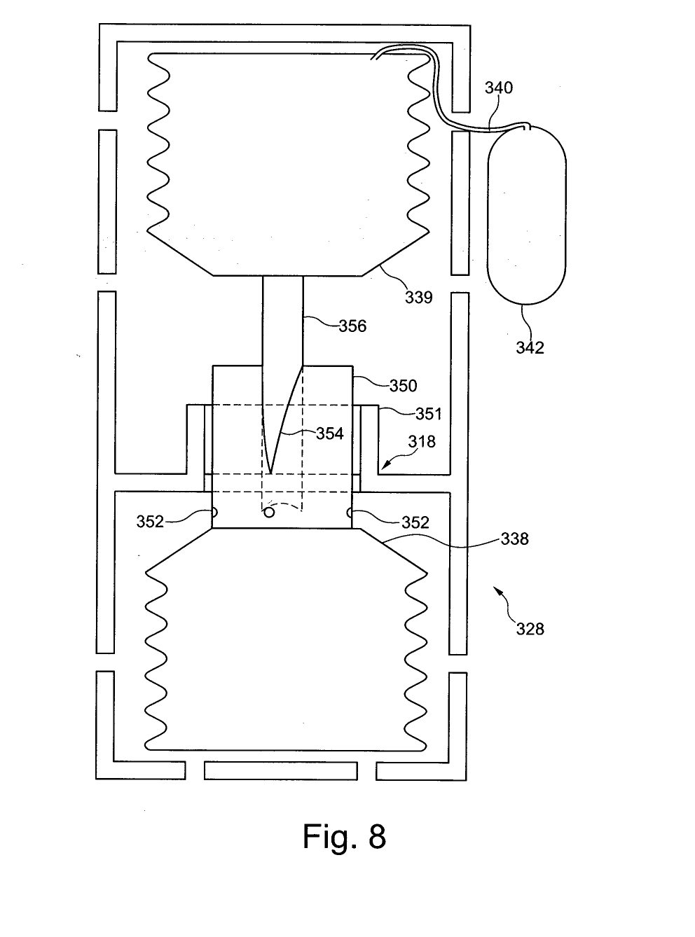

FIG. 8 shows one further possible embodiment of a clip 328 which clip 328 comprises a possible embodiment of a valve 318. Inside the clip 328 is indicated a first bellow, 338 which bellow contains a gas. Further is indicated a second bellow 339 which by a tube 340 is connected to a bulb 342. The bulb 342 and the bellow 339 contain a second refrigerant which probably is a refrigerant that is partly liquid and partly in gaseous form. The second refrigerant or maybe a mixture of refrigerants is selected together with the amount filled into the bellow 339 and the bulb 342 for achieving an efficient and quick response to temperature changes. The actual response temperature can efficiently be adjusted by one of the above-mentioned parameters so that the refrigerant or a mixture of refrigerants could be selected, and also the amounts of liquid and gaseous refrigerant filled into the volume of the bellow 339 and the bulb 342 could be selected to achieve correct temperature response. The valve 318 comprises a hollow piston 350 which is mechanically fastened to the top of the bellow 338. This piston 350 is moving in a cylinder 351. The piston comprises bleed holes 352 or maybe another kind of opening such as the slits 354 so the degree of opening will increase if the piston 350 is moved further downwards in the cylinder 351. Much different geometry for bleed holes could be used but only if a more or less symmetrical outflow of liquid refrigerant is achieved. Otherwise the result could be forces that act upon the cylinder 350 so it is pressed against the cylinder 351. Further a shaft 356 is indicated at the bellow 359 which shaft 356 ends inside the piston 350. It is to be understood that by increasing pressure in the bellow 339, the shaft 356 will be pressed further downwards which will lead to an opening of the valve 318, simply because the increasing pressure in the second bellow 339 will increase at a much higher rate than will the temperature in the bellow 338 which only comprises a gas and in this way operates as a spring.

In operation, the pressure above the valve will automatically act inside the piston 350, and if the pressure in the piston is higher than the pressure in the first bellow 338, the valve will start to open. Increasing pressure in the refrigerant in the valve will lead to a higher degree of opening. Therefore, in actual life, this will probably end up in a situation where the valve is placed at some point between closed and totally open position because the valve position will more or less automatically adjust its position to the actual cooling demand. In situations where the pressure in the valve is low, which could occur if condensing takes place in an outdoor environment, the pressure can be relatively low, but if a certain degree of cooling is demanded inside a housing, then if the bulb 342 is placed inside the housing, this increasing temperature will automatically lead to opening of the valve, so that a circulation starts. This could be very important if the valve is used in a thermo syphon.

As such this valve could be used not only in thermo siphon refrigeration systems, but also many other applications are possible. The use of this valve is also possible for other systems than refrigeration systems.

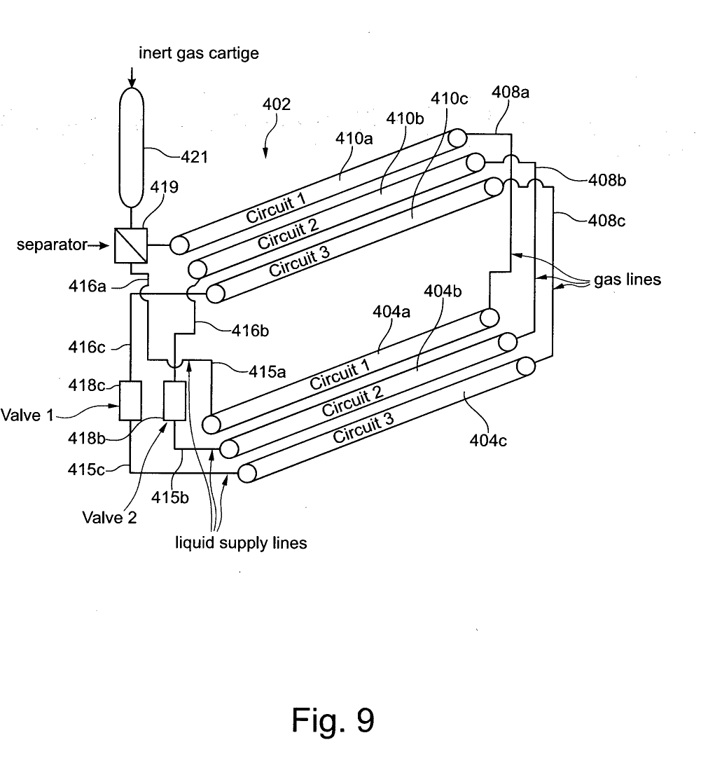

FIG. 9. discloses an alternative embodiment of the invention as shown in the previous figure. FIG. 9. shows a system 402 which system comprises three different and independent thermo syphon circuits. Each of the circuits comprises indoor evaporators 404 a-c in which liquid refrigerant is evaporated. Gas lines 408a-c transmit gaseous refrigerant into condensers 410 a-c. Line 410 is connected to a separator 419 which separator is further connected to a gas cartridge 421. The separator is further connected by line 416 back to the evaporator 404a. Further the condenser 410 b and 410 c connected by lines 416 b and 416 c to valves 418 b and 418 c. Further tubing 415 b and 415 c are connected to the evaporators 404 b and 404 c.

It is understood that in operation the first circuit probably operates in all temperature situations. However, the circuits 2 and 3 will start operating at increasing temperatures independently of the actual adjustment of the valves 418 b and 418 c. Therefore, in case of very low cooling demand, only the first circuit operating with the inactive gas added to the refrigerant will be in operation. By the correct selection of pressure of the inactive gas together with the correct design of refrigerant, it is possible to perform an automatic adjustment of the cooling effect. By decreasing system temperatures, increasing amounts of inactive gas can be mixed with the refrigerant and in that way change the evaporation profile of the refrigerant.

In order to explain the applied hybrid principle we use a 3 circuit thermo syphon, but the number of circuits are arbitrary since this would work with any number of circuits and/or combinations. The valves are extremely efficient as a device that will decrease or totally stop the Thermo syphon operation depending on the internal saturation state of the system which in many Thermo syphon has a very strong causality to the external ambient environment. Therefore, in many applications, it is a reasonable approximation to argue that the valve will operate in accordance to the external temperature and wind condition only. In some design that is exactly what is intended. However, in other design, where power dissipation varies heavily this can be inappropriate since the valves do not react to power dissipation. To solve this paradox, one additional circuit is implemented into the Thermo syphon system. In the attached drawing, this circuit is shown as circuit 1. This circuit contains a design gas, which is a mixture of at least two constituent's species. The idea is to facilitate the gas be designed in such a way that it loose efficiency at low temperatures and increase efficiency at higher temperatures. One of the key drivers to this is that at least one gas, the working gas, operates on the saturation curve in the phase diagram, while at least one of the gasses does not. At the high temperature limit the molar fraction of the working gas is very high. At decreasing temperatures the molar fraction of the working gas, continuously decrease. At the low temperature limit, the working gas bulk boiling process is prohibited and the Thermo syphon operation nearly ceases. In this limit, the Thermo syphon is highly dependent to power dissipation. To explain this: consider increased power dissipation. Once inside the temperature limit, Le Chatelier's principle will keep the temperature constant while boiling occur. The boiling is promotional to the power input which makes the system self-regulating. Now, the system is reacting heavily to power input. The principle of mixing one inert and one working gas is known from Variable Conductance Heat Pipes (VCHP). However, implementing this principle into a thermo syphon is very different. There are a few essential key components. A well designed separator. Such a device is not used in VCHP's. Also, one needs to facilitate that the separator is placed in an area where the condensable working fluid and the non-condensable gas is present. This is shown in the drawing. Also, the separator should be placed where the gas and liquid velocities are small. This way the huge density difference will separate the working fluid from the non-condensable gas, allowing the non-condensable gas flow to the inert gas cartridge. The cartridge could be advantageously divided into more cartridges. The first cartridge should ideally be placed above the liquid level of the condenser, while the following cartridges do not. Finally, circuits could contain both design gas, cartridge, separator and valves to obtain any number of the above described effect.

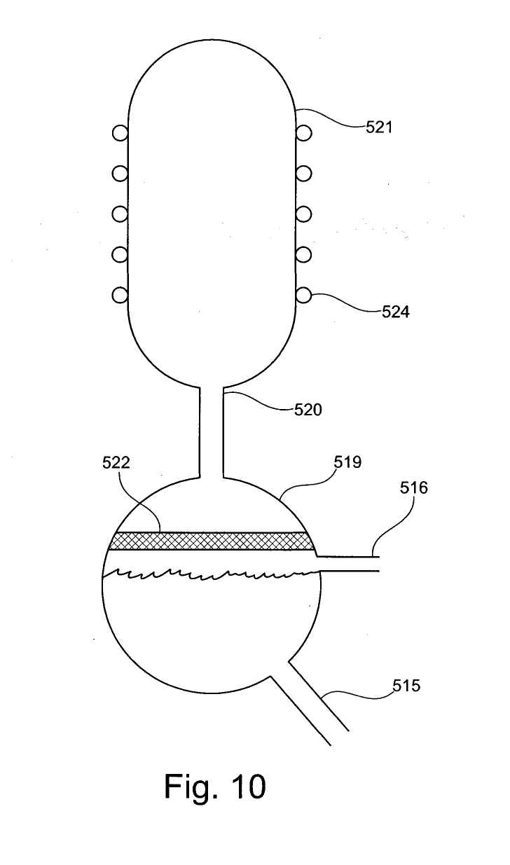

FIG. 10 shows a gas cartridge 521 connected to a separator 519. The gas cartridge 521 is connected to the separator 519 by tubing 520. This separator 519 is connected to a condenser by an inlet 516 so that the separator 519 receives mostly liquid refrigerant through the line 516. Further a line 515 is connected to the separator 519 which line 515 is connected to an evaporator. The separator 519 comprises a diaphragm 522 separating the volume inside the separator into a lower liquid volume and an upper gas volume. The diaphragm is designed so that it has a structure where only the small gas molecules can pass through and where the relatively large molecules of refrigerant are fully prevented from passing through the structure. Thereby is achieved that the gas cartridge 521 can be filled only with gas, and refrigerant is kept below.

Around the gas cartridge 521 a heating element 524 is indicated.

In operation, by changing the temperature of the gas cartridge 521, it is possible to change the pressure of the inactive gas and in that way control the amount of gas contained in the refrigerant.

In one situation it is possible to reduce the cooling effect of a thermo syphon simply by increasing the amount of inactive gas carried in the refrigerant. By high cooling effect it is possible to operate the system with the refrigerant with low contents of inactive gas, and if the cooling demand is decreasing, maybe the temperature of the gas cartridge 521 is increased by connecting electric power to the wire 524, it is possible to reduce the cooling effect simply by adding more of the inactive gas to the refrigerant. Hereby it is possible to achieve a thermo syphon cooling system where no mechanical parts are moving inside the system. Hereby can a system be obtained that can be controlled simply by switching on and off the heating element whereby it is possible to fully control the efficiency of the cooling system. Consequently, this cooling system is highly efficient cooling for example electronic systems for mobile communication placed at locations far away from normal service activities.

In some countries these radio stations are placed on mountains in order to achieve the best communication signal. Service on such systems can only be performed from helicopters. Therefore it is highly efficient to have a cooling system that can operate for very long periods of time with no need for service.

1-19. (canceled)

20. A cooling system comprising at least one thermosiphon with at least one indoor evaporator configured for evaporation of a liquid refrigerant and is heat conductively connected to indoor cooling fins, and which indoor evaporator by a first tubing is connected to at least one outdoor condenser, which first tubing conducts evaporated refrigerant from the evaporator to the outdoor condenser that is heat conductively connected to outdoor cooling fins for cooling the outdoor condenser, and which outdoor condenser relatively to the indoor evaporator is placed at a defined vertical distance to use the gravity to generate a flow of the liquid refrigerant from the outdoor condenser through a second tubing back to the indoor evaporator, wherein the second tubing comprises a valve with a valve seat and a moveable valve piston with—the valve piston being movable by a valve actuator so that the valve piston moves towards the valve seat for closing the valve for decreasing temperature of refrigerant in the evaporator, and
the valve piston being movable by the valve actuator, so that the valve piston moves away from the valve seat for opening the valve for increasing temperature of refrigerant in the evaporator, and
wherein the valve actuator is a bellow, which bellow comprises a non-condensable gas or one or more refrigerants.

21. The cooling system according to claim 20, wherein the bellow is configured with characteristics of a spring.

22. The cooling system according to claim 20, wherein the bellow is positioned to expand or contract in the flow direction in the second tubing.

23. The cooling system according to claim 20, wherein the bellow is substantially inside or embedded within the second tubing.

24. The cooling system according to claim 20, wherein the bellow is of a metallic or a bimetallic material.

25. The cooling system according to claim 20, wherein the valve is formed as a valve unit comprising a valve seat formed in a clip with one or more legs having fastening means for supporting a reference plate, to support a first end of the bellow, which bellow at a second end comprises the valve piston.

26. The cooling system according to claim 25, wherein the bellow comprises an inner support with a tube placed inside the bellow and which inner support comprises a collar that is fastened to the first end of the bellow.

27. The cooling system according to claim 25, wherein the clip combined with the bellow and the inner support from the valve unit, which valve unit is placed inside a section of a tube.

28. The cooling system according to claim 20, wherein the valve comprises a cylinder in which cylinder a hollow piston is operating, which cylinder is mechanically connected to the first bellow, which hollow piston comprises a plurality of bleed openings, which bleed openings by movement of the piston in relation to the cylinder performs a gradual opening of the valve.

29. The cooling system according to claim 20, wherein the system comprises at least one second bellow that by at least one tube is connected to at least one bulb, which second bellow and the bulb contain a second refrigerant, which second refrigerant is partly liquid and partly gas when in normal operation of the cooling system, where the bulb is placed inside a housing and in which bulb the pressure depends on the indoor temperature, which increasing indoor temperature results in increasing pressure in both the bulb and in the second bellow, which second bellow forces the valve to open.

30. The cooling system according to claim 20, wherein the cooling system comprises at least a first circuit configured to operate continuously and which first circuit comprises a design gas with a refrigerant or refrigerant mixture, which design gas further comprises an inactive gas that is in gas form in all operational conditions of the cooling system, and which first circuit comprises a separator that is connected to a at least one inactive gas cartridge.

31. The use of a system as disclosed in claim 20 for cooling electronic systems, wherein electronic systems are placed inside a housing, which electronic systems generate heat, whereby the inner of the housing need cooling, which cooling is performed with at least one thermosiphon, which evaporator of the thermosiphon is placed inside the housing of the electronic system, which condenser of the thermosiphon is placed outside the housing.

32. A method of operating a cooling system as defined in claim 20, including the steps of:
(a) evaporating refrigerant in an evaporator for generation of a refrigerant gas,
(b) flowing the refrigerant gas in a tubing towards a condenser placed a gravity level higher than the evaporator,
(c) condensing the refrigerant gas in the condenser for generation of the liquid refrigerant,
(d) flowing the liquid refrigerant in a tubing towards a normally closed valve,
(e) opening the valve for increasing temperature of refrigerant in the evaporator and closing the valve for decreasing temperature of refrigerant in the evaporator, wherein the opening and closing of the valve is performed by the valve actuator comprising a bellow containing a non-condensable gas or one or more refrigerants, and
(f) forcing the liquid refrigerant to flow by gravity in a piping back towards the evaporator.

33. The method of operating a cooling system according to claim 32, wherein step (e) is performed with the use of a first bellow and a second bellow operatively configured.

34. The method of operating a cooling system according to claim 32, wherein the steps are performed in parallel by a plurality of circuits where at least one circuit operates continuously and uses a design gas with a refrigerant or refrigerant mixture that further comprises an inactive gas, which design gas is gaseous in all operational conditions of the cooling system, and which first circuit uses a separator that is supplied with least one inactive gas from a cartridge.
